(19) United States
(12) Patent Application Publication
(10) Pub. No.: US 2017/0256668 A1
(43) Pub. Date: Sep. 7, 2017

(54) SEMICONDUCTOR EPITAXIAL WAFER AND METHOD OF PRODUCING THE SAME, AND METHOD OF PRODUCING SOLID-STATE IMAGE SENSING DEVICE

(71) Applicant: SUMCO CORPORATION, Tokyo (JP)

(72) Inventors: Ryosuke OKUYAMA, Tokyo (JP); Takeshi KADONO, Tokyo (JP); Kazunari KURITA, Tokyo (JP)

(73) Assignee: SUMCO CORPORATION, Tokyo (JP)

(21) Appl. No.: 15/506,457

(22) PCT Filed: May 21, 2015
(86) PCT No.: PCT/JP2015/065324

§ 371 Date: Feb. 24, 2017

(30) Foreign Application Priority Data
Aug. 28, 2014 (JP) 2014-174330

(51) Int. Cl. H01L 31/18; H01L 31/0288; H01L 27/146

(52) U.S. Cl. CPC H01L 31/1804; H01L 27/14687; H01L 27/1464; H01L 31/1864; H01L 31/0288

(57) ABSTRACT

To provide a semiconductor epitaxial wafer having an epitaxial layer with excellent crystallinity, the semiconductor epitaxial wafer is a semiconductor epitaxial wafer in which an epitaxial layer is formed on a surface of a semiconductor wafer, and the peak of the hydrogen concentration profile detected by SIMS lies in a surface portion of the semiconductor wafer on the side where the on the side where the epitaxial layer is formed.

### TECHNICAL FIELD

This disclosure relates to a semiconductor epitaxial wafer and a method of producing the same, and a method of producing a solid-state image sensing device.

### BACKGROUND

Semiconductor epitaxial wafers in which an epitaxial layer is formed on a semiconductor wafer are used as device substrates of various semiconductor devices such as metal-oxide-semiconductor field-effect transistors (MOSFETs), dynamic random access memories (DRAMs), power transistors, and back-illuminated solid-state image sensing devices.

In recent years, for example, back-illuminated solid-state image sensing devices are widely used in digital video cameras and mobile phones such as smart phones, since they can directly receive light from the outside, and take sharper images or motion pictures even in dark places and the like due to the fact that a wiring layer and the like thereof are disposed at a lower layer than a sensor unit.

As semiconductor devices are increasingly developed to be miniaturized and to have higher performance in recent years, semiconductor epitaxial wafers used as device substrates are required to have higher quality in order to improve the device characteristics. For the purpose of further improvement in the device characteristics, techniques for improving crystal quality using oxygen precipitation heat treatment, gettering techniques for preventing heavy metal contamination in epitaxial growth, and the like are developed.

For example, JP 2013-197373 A (PTL 1) discloses a method of producing an epitaxial wafer in which an epitaxial layer is formed after performing oxygen precipitation heat treatment on a silicon substrate, in which the conditions for the oxygen precipitation heat treatment are controlled such that the epitaxial layer has a leakage current of 1.5E−10 A or less after the formation of the epitaxial layer.

Further, regarding gettering techniques, the applicant of the present application proposes in JP 2010-287855 A (PTL 2) that a silicon wafer including a contamination protection layer formed at a depth of 1 μm or more and 10 μm or less by introducing non-metal ions at a dose of 1×10¹³/cm or more and 3×10¹⁴/cm² or less.

### CITATION LIST

### Patent Literature

PTL 1: JP 2013-197373 A

PTL 2: JP 2010-287855 A

### SUMMARY

### Technical Problem

As described in PTL 1 and PTL 2, various attempts to increase the quality of semiconductor epitaxial wafers have been made. Specifically, various attempts to improve the crystallinity such as reduction of surface pits in a surface portion of an epitaxial layer have been made to date; however, an interior portion of an epitaxial layer has been considered to have sufficiently high crystallinity, so that no technique for increasing the crystallinity inside the epitaxial layer itself has been proposed. If the crystallinity of an interior part of an epitaxial layer can be increased further, improvement in the device characteristics can be expected.

### Solution to Problem

In view of the above problem, it could be helpful to provide a semiconductor epitaxial wafer including an epitaxial layer with higher crystallinity and a method of producing the same.

The inventors of the present invention made various studies to solve the above problem, and focused on making the peak of the hydrogen concentration profile lie in a surface portion of a semiconductor wafer of a semiconductor epitaxial wafer, on the side where an epitaxial layer is formed. Here, as is known, even if hydrogen being a light element is ion-implanted to a semiconductor wafer, hydrogen diffuses due to heat treatment in the formation of an epitaxial layer. Therefore, hydrogen has not been considered to contribute to the improvement in the device quality of a semiconductor device manufactured using a semiconductor epitaxial wafer. Even when the hydrogen concentration of a semiconductor epitaxial wafer obtained by performing hydrogen ion implantation on a semiconductor wafer under typical conditions followed by forming an epitaxial layer on a surface of the semiconductor wafer was actually measured, the measured hydrogen concentration was less than the detection limit of secondary ion mass spectrometry (SIMS) and the effect of hydrogen had not been known. To date, there has been no known literature relating to the concentration peak of hydrogen, in an amount exceeding the detection limit of SIMS, appearing in a surface portion of a semiconductor wafer on the side where an epitaxial layer is formed, and to the behavior of such hydrogen. However, the results of experiments carried out by the inventors revealed that the crystallinity of an epitaxial layer of the semiconductor epitaxial wafer in which the hydrogen concentration profile peak lied in a surface portion of the semiconductor wafer on the side where the epitaxial layer was formed was obviously improved. Moreover, the inventors found that hydrogen in the surface portion of the semiconductor wafer contributes to the improvement in the crystallinity of the epitaxial layer. Thus, they accomplished the present invention. The inventors also developed a method of producing such a semiconductor epitaxial wafer in a preferred manner.

Specifically, we propose the following features.

A semiconductor epitaxial wafer of this disclosure is a semiconductor epitaxial wafer in which an epitaxial layer is formed on a surface of a semiconductor wafer, in which a peak of a hydrogen concentration profile detected by SIMS lies in a surface portion of the semiconductor wafer on a side where the epitaxial layer is formed.

Here, the peak of the hydrogen concentration profile preferably lies at a position within a depth range of 150 nm in the thickness direction from the surface of the semiconductor wafer. Further, the peak concentration of the hydrogen concentration profile is preferably 1.0×1017 atoms/cm3 or more.

Preferably, the semiconductor wafer has a modifying layer containing carbon as a solid solution in the surface portion, and the half width of the peak of a carbon concentration profile of the modifying layer in the direction of the thickness of the semiconductor wafer is 100 nm or less.

On that occasion, the peak of the carbon concentration profile more preferably lies at a position within a depth range of 150 nm in the thickness direction from the surface of the semiconductor wafer.

Further, the semiconductor wafer is preferably a silicon wafer.

A method of producing the semiconductor epitaxial wafer includes: a first step of irradiating a surface of a semiconductor wafer with cluster ions including hydrogen as a constituent element; and a second step of forming an epitaxial layer on the surface of the semiconductor wafer after the first step. In the first step, a beam current value of the cluster ions is 50 μA or more.

Here, in the first step, the beam current value is preferably 5000 μA or less.

Further, it is preferred that the cluster ions further include carbon as a constituent element.

Here, the semiconductor wafer is preferably a silicon wafer.

Further, in a method of producing a solid-state image sensing device of this disclosure, a solid-state image sensing device is formed on the epitaxial layer of any one of the above epitaxial wafers or the epitaxial wafer produced by any one of the above production methods.

### Advantageous Effect

We can provide a semiconductor epitaxial wafer having an epitaxial layer with higher crystallinity achieved because the peak of the hydrogen concentration profile detected by SIMS lies in a surface portion of the semiconductor wafer on the side where the epitaxial layer is formed. We can also provide a method of producing a semiconductor epitaxial wafer including an epitaxial layer with higher crystallinity.

### BRIEF DESCRIPTION OF THE DRAWINGS

In the accompanying drawings:

FIG. 1 is a schematic cross-sectional view illustrating a semiconductor epitaxial wafer 100 according to one of the disclosed embodiments;

FIG. 2 is a schematic cross-sectional view illustrating a semiconductor epitaxial wafer 200 according to a preferred embodiment;

FIG. 3 is a schematic cross-sectional views illustrating a method of producing a semiconductor epitaxial wafer 200 according to one of the disclosed embodiments;

FIG. 4A is a schematic view illustrating the irradiation mechanism for irradiation with cluster ions;

FIG. 4B is a schematic view illustrating the implantation mechanism for implanting a monomer ion;

FIG. 5A is a graph showing the concentration profiles of carbon and hydrogen in a silicon wafer having been irradiated with cluster ions in Reference Example 1;

FIG. 5B is a TEM cross-sectional view of a surface portion of the silicon wafer according to Reference Example 1;

FIG. 5C is a TEM cross-sectional view of a surface portion of a silicon wafer according to Reference Example 2;

FIG. 6A is a graph showing the concentration profiles of carbon and hydrogen in an epitaxial silicon wafer according to Example 1-1 after the formation of an epitaxial layer;

FIG. 6B is the concentration profile of hydrogen in an epitaxial silicon wafer according to Comparative Example 1-1;

FIG. 7 is a graph showing the TO-line (Transverse Optical) intensity of epitaxial silicon wafers according to Example 1-1 and Conventional Example 1-1;

FIG. 8 is a graph showing the concentration profiles of carbon and hydrogen in an epitaxial silicon wafer according to Example 2-1; and

FIG. 9 is a graph showing the TO-line intensity of epitaxial silicon wafers according to Example 2-1 and Conventional Example 2-1.

### DETAILED DESCRIPTION

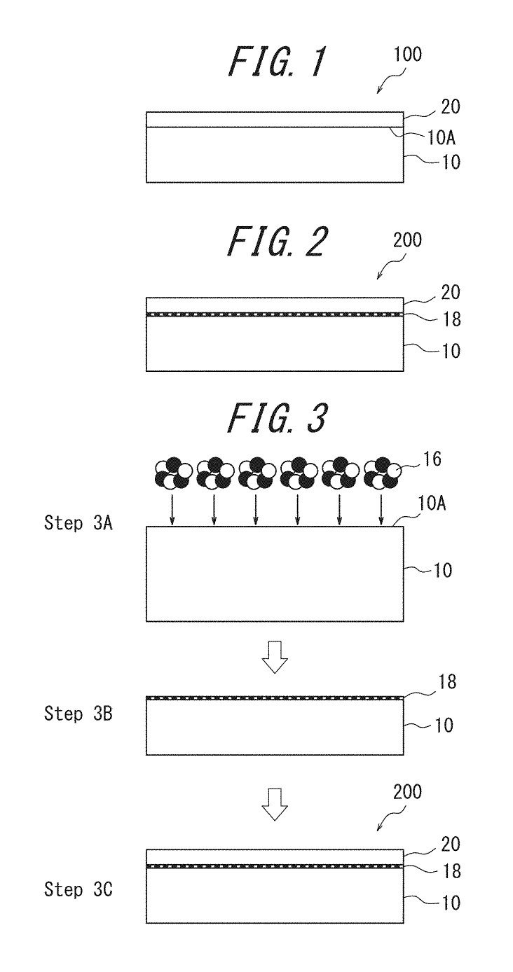

Embodiments will now be described in detail with reference to the drawings. In principle, like components are denoted by the same reference numerals, and the description will not be repeated. In FIGS. 1 to 3, in order to simplify the drawings, a semiconductor wafer 10, a modifying layer 18, and an epitaxial layer 20 are enlarged in terms of the thickness, so the thickness ratio does not conform to the actual ratio.

(Semiconductor Epitaxial Wafer)

With respect to a semiconductor epitaxial wafer 100 according to one of the disclosed embodiments is a semiconductor epitaxial wafer, in which an epitaxial layer 20 is formed on a surface 10A of the semiconductor wafer 10 as shown in FIG. 1; the peak of the hydrogen concentration profile detected by SIMS lies in a surface portion of the semiconductor wafer 10 on the side where the epitaxial layer 20 is formed. The epitaxial layer 20 is used as a device layer for producing a semiconductor device such as a back-illuminated solid-state image sensing device. The features will now be described in order in detail.

The semiconductor wafer 10 is, for example, a bulk single crystal wafer made of silicon or a compound semiconductor (GaAs, GaN, or SiC), in which the surface 10A does not have an epitaxial layer. When producing a back-illuminated solid-state image sensing device, a bulk single crystal silicon wafer is typically used. A silicon wafer may be prepared by growing a single crystal silicon ingot by the Czochralski process (CZ process) or floating zone melting process (FZ process) and slicing it with a wire saw or the like. Note that a semiconductor wafer 10 to which carbon and/or nitrogen are added may be used to obtain gettering capability. Alternatively, a given dopant may be added at a predetermined concentration and the thus obtained semiconductor wafer 10 which is a substrate of so-called n+ type or p+ type, or n− type or p− type can be used.

A silicon epitaxial layer can be given as an example of the epitaxial layer 20, and the silicon epitaxial layer can be formed under typical conditions. For example, a source gas such as dichlorosilane or trichlorosilane can be introduced into a chamber using hydrogen as a carrier gas and the source material can be epitaxially grown on the silicon wafer 10 by CVD at a temperature in the range of approximately 1000° C. to 1200° C., although the growth temperature depends also on the source gas to be used. The epitaxial layer 20 preferably has a thickness in the range of 1 μm to 15 μm. When the thickness is less than 1 μm, the resistivity of the epitaxial layer 20 would change due to out-diffusion of dopants from the semiconductor wafer 10, whereas a thickness exceeding 15 μm would affect the spectral sensitivity characteristics of the solid-state image sensing device.

Here, one of the unique feature of the semiconductor epitaxial wafer 100 is that the peak of the hydrogen concentration profile detected by SIMS lies in a surface portion of the semiconductor wafer 10 on the side where the epitaxial layer 20 is formed. Considering the detection technology using SIMS at this time, the lower limit of detection of the hydrogen concentration by SIMS herein is 7.0×10¹⁶ atoms/cm³. The technical meaning of employing such a feature will be described with the operation and effect.

Heretofore, ion-implanting hydrogen into a semiconductor epitaxial wafer such that hydrogen can be localized in the semiconductor wafer at a high concentration has not been considered to contribute to the improvement in the semiconductor device characteristics. Under typical ion-implanting conditions of hydrogen into a semiconductor wafer, since hydrogen being a lightweight element is diffused outward due to heat caused due to the formation of an epitaxial layer, hydrogen diffuses outward after the formation of the epitaxial layer and little hydrogen remains in the semiconductor wafer. Even when the hydrogen concentration profile of a semiconductor epitaxial wafer subjected to typical hydrogen ion implantation conditions is actually analyzed by SIMS, the hydrogen concentration after the formation of an epitaxial layer is less than the detection limit. According to the results of experiments carried out by the inventors (experimental conditions will be described in detail in Examples below), with predetermined requirements met, a high hydrogen concentration region can be formed in a surface portion of a semiconductor wafer on the side where an epitaxial layer is formed, and the inventors focused on the behavior of hydrogen in this case. Thus, the following facts were revealed.

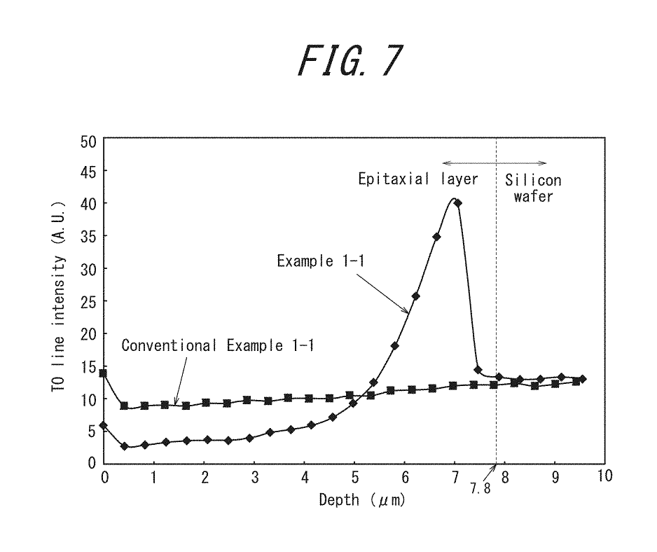

Although the details will be described in Examples below, the inventors observed the difference in the crystallinity of an epitaxial layer between a semiconductor epitaxial wafer 100 having the peak of the hydrogen concentration profile and a conventional semiconductor epitaxial wafer having no peak of the hydrogen concentration profile by cathode luminescence (CL) spectroscopy. Note that the CL spectroscopy is a technique of measuring crystal defects, in which a sample is irradiated with electron beams to detect exciting light produced due to transition from around the base of the conduction band to around the top of the valance band. FIG. 7 is a graph showing the TO-line intensities in the thickness direction of the disclosed semiconductor epitaxial wafer 100 and a conventional semiconductor epitaxial wafer, in which a depth of 0 μm corresponds to the surface of the epitaxial layer and a depth of 7.8 μm corresponds to the boundary surface between the epitaxial layer and the semiconductor wafer. Note that TO-line (Transverse Optical) refers to a spectrum specific to Si element corresponding to the band gap of Si observed by CL spectroscopy. Stronger TO-line intensity means higher crystallinity of Si.

As shown in FIG. 7 of which details will be described below, the disclosed semiconductor epitaxial wafer 100 has the peak of the TO-line intensity in the epitaxial layer 20 on the side close to the semiconductor wafer 10. On the other hand, the conventional semiconductor epitaxial wafer has the TO-line intensity that tends to gradually decrease from the boundary surface between the semiconductor wafer and the epitaxial layer toward the surface of the epitaxial layer. Note that the value of the surface of the epitaxial layer (depth of 0 μm) is judged to be an outlier which is due to the influence of the surface level on the surface being the outermost surface. Next, assuming that a device is fabricated using the semiconductor epitaxial wafer 100, the inventors observed the TO-line intensity of the case where heat treatment simulating device fabrication is performed on the semiconductor epitaxial wafer 100. As shown in FIG. 9 of which details will be described below, the epitaxial layer 20 of the disclosed semiconductor epitaxial wafer 100 was experimentally revealed to maintain the peak of the TO-line intensity and meanwhile have almost the same level of TO-line intensity as the epitaxial layer of the conventional semiconductor epitaxial wafer in areas other than the peak. That is, the semiconductor epitaxial wafer 100 having the peak of the hydrogen concentration profile as disclosed was found to have the epitaxial layer 20 with higher crystallinity than conventional considering all the factors involved.

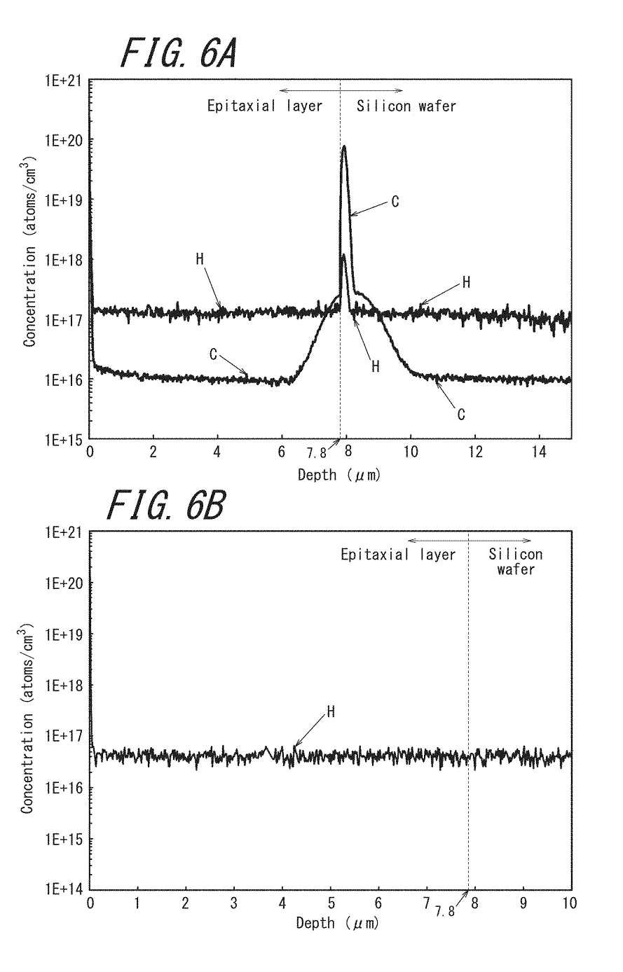

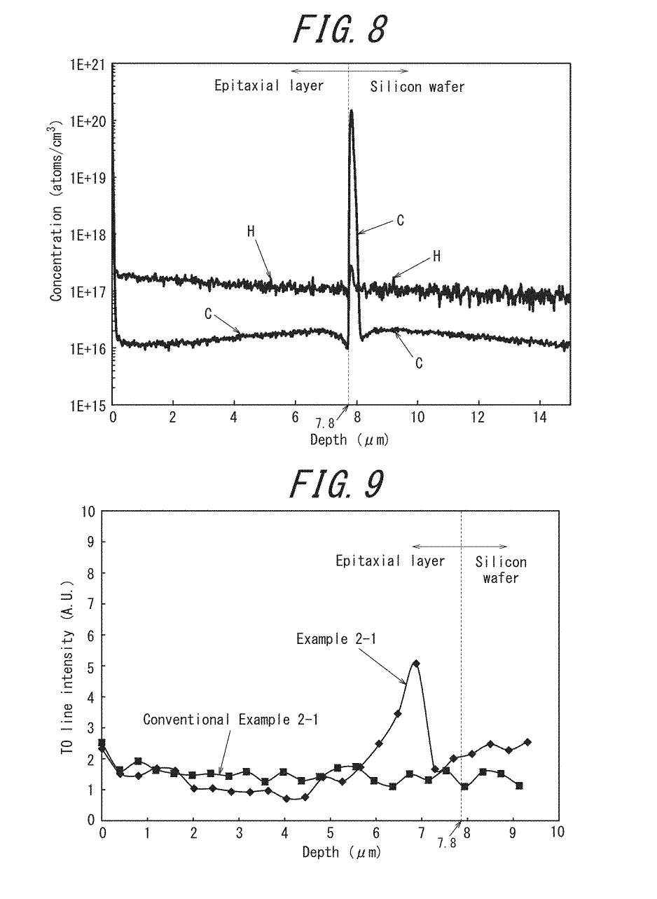

Although the theoretical background of this phenomenon is still unclear and this disclosure is not bound to any theory, the inventors reason as follows. The details will be described later, yet FIG. 6 shows the hydrogen concentration profile of the semiconductor epitaxial wafer 100 immediately after the formation of the epitaxial layer, whereas FIG. 8 is a graph showing the hydrogen concentration profile of the semiconductor epitaxial wafer 100 after performing heat treatment simulating device fabrication. A comparison of the peaks of the hydrogen concentrations in FIG. 6 and FIG. 8 shows that the peak concentration of hydrogen is reduced by performing the heat treatment simulating device fabrication. Considering the variation trends of the hydrogen concentration and the TO-line intensity before and after the simulated heat treatment, point defects in the epitaxial layer 20 are assumed to be passivated by hydrogen present at high concentration in a surface portion of the semiconductor wafer 10 due to the heat treatment simulating device fabrication, thereby increasing the crystallinity of the epitaxial layer 20.

As described above, the semiconductor epitaxial wafer 100 of this embodiment has the epitaxial layer 20 with higher crystallinity. The semiconductor epitaxial wafer 100 provided with the epitaxial layer 20 can be used to improve the device characteristics of a semiconductor device using the wafer.

Note that the above-described operation and effect can be obtained when the peak of the hydrogen concentration profile lies at a position within a depth range of 150 nm in the thickness direction from the surface 10A of the semiconductor wafer 10. Accordingly, the portion corresponding to the above position can be defined as the surface portion of the disclosed semiconductor wafer. The above operation and effect can be more ensured when the peak of the hydrogen concentration profile lies at a position within a depth range of 100 nm in the thickness direction from the surface 10A of the semiconductor wafer 10. Note that since it is physically impossible that the peak of the hydrogen concentration profile lies at the outermost surface (depth of 0 nm) of the wafer, the peak shall lie at a position in a depth range of at least 5 nm or more.

Further, in terms of ensuring the above operation and effect, the peak concentration of the hydrogen concentration profile is preferably 1.0×10¹⁷ atoms/cm³ or more, particularly preferably 1.0×10¹⁸ atoms/cm³ or more. Although there is no intention to limit the invention, considering industrial production of the semiconductor epitaxial wafer 100, the upper limit of the peak concentration of hydrogen may be 1.0×10²² atoms/cm³.

Here, in a preferred semiconductor epitaxial wafer 200 of this disclosure, the semiconductor wafer 10 has a modifying layer 18 containing carbon as a solid solution in the surface portion as shown in FIG. 2, and the half width (FWHM: Full Width at Half Maximum) of the peak of the carbon concentration profile of the modifying layer 18 in the thickness direction of the semiconductor wafer 10 is preferably 100 nm or less. The modifying layer 18 is a region where carbon is localized as a solid solution at crystal interstitial positions or substitution positions in the crystal lattice of the surface portion of the semiconductor wafer, the region serving as a strong gettering site. Further, in terms of achieving higher gettering capability, the half width is preferably 85 nm or less, and the lower limit thereof can be set to 10 nm. “The carbon concentration profile in the thickness direction” herein means the concentration profile in the thickness direction measured by SIMS.

Further, in terms of obtaining higher gettering capability, in addition to the hydrogen and carbon given above, elements other than the main material of the semiconductor wafer (silicon in the case of using a silicon wafer) preferably constitute the solid solution in the modifying layer 18.

Moreover, in terms of obtaining higher gettering capability, in the semiconductor epitaxial wafer 200, the peak of the carbon concentration profile preferably lies at a position in a depth range of 150 nm or less in the thickness direction from the surface 10A of the semiconductor wafer 10. The peak concentration of the carbon concentration profile is preferably 1×10¹⁵ atoms/cm³ or more, more preferably in the range of 1×10¹⁷ atoms/cm³ to 1×10²² atoms/cm³, still more preferably in the range of 1×10¹⁹ to 1×10²¹ atoms/cm³.

Note that the thickness of the modifying layer 18 is defined such that the carbon concentration is in the above concentration profile but higher than the background. For example, the thickness may be in the range of 30 nm to 400 nm.

(Method of Producing Semiconductor Epitaxial Wafer)

Next, an embodiment of a method of producing the semiconductor epitaxial wafer 200 disclosed hereinbefore will be described. A method of producing the semiconductor epitaxial wafer 200 according the above embodiment includes a first step of irradiating the surface 10A of the semiconductor wafer 10 with cluster ions 16 including hydrogen as a constituent element (Step 3A and Step 3B in FIG. 3); and a second step of forming an epitaxial layer 20 on the surface 10A of the semiconductor wafer 10 after the first step (Step 3C of FIG. 3) as shown in FIG. 3. Further, in the first step, a beam current value of the cluster ions 16 is 50 μA or more. Step 3C of FIG. 3 is a schematic cross-sectional view of the semiconductor epitaxial wafer 200 obtained by this production method. The steps will now be described in order in detail.

First, a semiconductor wafer 10 is prepared. Next, as shown in Step 3A and Step 3B of FIG. 3, the first step is performed to irradiate the surface 10A of the semiconductor wafer 10 with the cluster ions 16 including hydrogen as a constituent element. Here, in order to make the peak of the hydrogen concentration profile detected by SIMS lie in the surface portion of the semiconductor wafer 10 on the epitaxial layer 20 side, it is important that the beam current value of the cluster ions 16 is 50 μA or more in the first step. As a result of irradiation with the cluster ions 16 including hydrogen under the above current value condition, hydrogen included in the constituent elements of the cluster ions are localized as a solid solution in the surface portion of the semiconductor wafer 10 on the surface 10A (that is the irradiated plane) side at a concentration exceeding the equilibrium concentration.

Note that “cluster ions” herein mean clusters formed by aggregation of a plurality of atoms or molecules, which are ionized by being positively or negatively charged. A cluster is a bulk aggregate having a plurality of (typically 2 to 2000) atoms or molecules bound together.

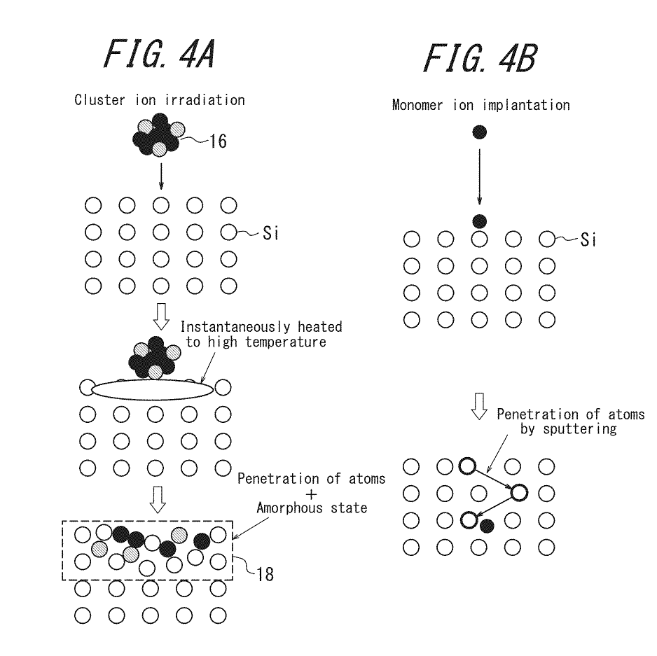

The difference in the solid solution behavior between the case of irradiating the semiconductor wafer 10 with cluster ions and the case of implanting monomer ions is described as below. That is, for example, when monomer ions consisting of certain elements are implanted into a silicon wafer as the semiconductor wafer, the monomer ions sputter silicon atoms in the silicon wafer and are implanted to a predetermined depth position in the silicon wafer, as shown in FIG. 4B. The implantation depth depends on the kinds of the constituent elements of the implantation ions and the acceleration voltage of the ions. Accordingly, the concentration profile of the certain elements in the depth direction of the silicon wafer is relatively broad and the area where the implanted certain elements are present ranges from approximately 0.5 μm to 1 μm from the surface. When the implantation is performed simultaneously with a plurality of species of ions at the same energy, lighter elements are implanted more deeply, in other words, elements are implanted at different positions depending on their mass. Accordingly, the concentration profile of the implanted elements is broader in such a case. Further, in the formation of an epitaxial layer after ion implantation, the implanted elements are diffused due to heat, which is also a factor of the broader concentration profile.

Monomer ions are typically implanted at an acceleration voltage of about 150 keV to 2000 keV. However, since the ions collide with silicon atoms with the energy, which results in the degradation of crystallinity of the surface portion of the silicon wafer, to which the monomer ions are implanted. Accordingly, the crystallinity of an epitaxial layer to be grown later on the wafer surface tends to be degraded. Further, the higher the acceleration voltage is, the more the crystallinity tends to be degraded.

On the other hand, when a silicon wafer is irradiated with cluster ions as shown in FIG. 4A, the cluster ions 16 are instantaneously turned into a high temperature state of about 1350° C. to 1400° C. due to the irradiation energy, thus melting silicon. After that, the silicon is rapidly cooled to form a solid solution of the constituent elements of the cluster ions 16 in the vicinity of the surface of the silicon wafer. The concentration profile of the constituent elements in the depth direction of the silicon wafer is sharper as compared with the case of using monomer ions, although depending on the acceleration voltage and the cluster size of the cluster ions. The region where the constituent elements used for the irradiation are present is a region of approximately 500 nm or less (for example, about 50 nm to 400 nm). Further, as compared with monomer ions, since the ions used for irradiation form clusters, the cluster ions are not channeled through the crystal lattice, and thermal diffusion of the constituent elements is suppressed, which also leads to the sharp concentration profile. Consequently, the constituent elements of the cluster ions 16 are precipitated at a high concentration in a localized region.

Here, as described above, since hydrogen is a lightweight element, hydrogen ions easily diffuse for example due to heat treatment for forming the epitaxial layer 20 and tend to hardly remain in the semiconductor wafer after the formation of the epitaxial layer. Therefore, only locally and heavily irradiating the region where hydrogen precipitates by cluster ion irradiation is not sufficient. It is important for suppressing the hydrogen diffusion in heat treatment to set the beam current value of the cluster ions 16 to 50 μA or more so that the surface 10A of the semiconductor wafer 10 is irradiated with hydrogen ions for a relatively short time to increase damage to the surface portion. A beam current value of 50 μA or more can increase damage, which allows the peak of the hydrogen concentration profile detected by SIMS lie in the surface portion of the semiconductor wafer 10 on the epitaxial layer 20 side even after the subsequent formation of the epitaxial layer 20. When the beam current value is less than 50 μA, damage to the surface portion of the semiconductor wafer 10 is not sufficient and hydrogen would diffuse due to heat treat treatment for the formation of the epitaxial layer 20. The beam current value of the cluster ions 16 can be adjusted for example by changing the conditions for the decomposition of the source gas in the ion source.

After the above first step, the second step of forming the epitaxial layer 20 on the surface 10A of the semiconductor wafer 10. The epitaxial layer 20 in the second step has been described above is performed.

Thus, the method of producing the semiconductor epitaxial wafer 200 can be provided.

Note that even after the formation of the epitaxial layer 20, in order to ensure that the peak of the hydrogen concentration profile detected by SIMS lies in the surface portion of the semiconductor wafer 10, the beam current value of the cluster ions 16 is preferably 100 μA or more, more preferably 300 μA or more.

When the beam current value is excessively high, epitaxial defects would be excessively formed in the epitaxial layer 20. Therefore, the beam current value is preferably 5000 μA or less.

The conditions for the irradiation with the cluster ions 16 will now be described. First, the constituent elements of the cluster ions 16 used for irradiation other than hydrogen are not limited in particular; for example, they can include carbon, boron, phosphorus, arsenic, and/or the like. However, in terms of obtaining higher gettering capability, the cluster ions 16 preferably include carbon as a constituent element. This leads to the formation of the modifying layer 18 having a solid solution of carbon. Carbon atoms at a lattice site have a smaller covalent radius than silicon single crystals, and for this reason a compression site is produced in the silicon crystal lattice, which results in a gettering site attracting impurities in the lattice.

Further, the elements for irradiation preferably include elements other than hydrogen and carbon. In particular, irradiation is preferably performed using one or more dopant elements selected from the group consisting of boron, phosphorus, arsenic, and antimony in addition to hydrogen and carbon.

Since the kinds of metals to be efficiently gettered depend on the kinds of the solid solution elements, solid solutions of a multiple kinds of elements can cover a wider variety of metal contaminations. For example, carbon can efficiently getter nickel (Ni), whereas boron can efficiently getter copper (Cu) and iron (Fe).

A source compound to be ionized is not limited in particular; however, ethane, methane, or the like can be used as a carbon source compound that can be ionized, whereas diborane, decaborane (B₁₀H₁₄), or the like can be used as a boron source compound that can be ionized. For example, when a mixed gas of dibenzyl and decaborane is used as a material gas, hydrogen compound clusters can be produced, in which carbon, boron, and hydrogen are aggregated. Alternatively, when cyclohexane (C₆H₁₂) is used as a material gas, cluster ions formed from carbon and hydrogen can be produced. In particular, CₙHₘ (3≦n≦16, 3≦m≦10) clusters produced from pyrene (C₁₆H₁₀), dibenzyl (C₁₄H₁₄), or the like is preferably used as the carbon source compound. This is because ion beams of small-sized clusters can easily be controlled.

The cluster size can be set to 2 to 100, preferably 60 or less, more preferably 50 or less. The cluster size can be adjusted by controlling the pressure of gas ejected from a nozzle, the pressure of a vacuum vessel, the voltage applied to the filament in the ionization, and the like. The cluster size is determined by finding the cluster number distribution by mass spectrometry using the oscillating quadrupole field or by time-of-flight mass spectrometry, and finding the mean value of the number of clusters.

The cluster ions may include a variety of clusters depending on the binding mode, and can be generated, for example, by known methods described in the following documents. Methods of generating gas cluster beam are described in (1) JP 09-041138 A and (2) JP 04-354865 A. Methods of generating ion beam are described in (1) Junzo Ishikawa, “Charged particle beam engineering”, ISBN 978-4-339-00734-3 CORONA PUBLISHING, (2) The Institution of Electrical Engineers of Japan, “Electron/Ion Beam Engineering”, Ohmsha, ISBN 4-88686-217-9, and (3) “Cluster Ion Beam—Basic and Applications”, THE NIKKAN KOGYO SHIMBUN, ISBN 4-526-05765-7. In general, a Nielsen ion source or a Kaufman ion source is used for generating positively charged cluster ions, whereas a high current negative ion source using volume production is used for generating negatively charged cluster ions.

The acceleration voltage of the cluster ions as well as the cluster size has an influence on the peak position of the concentration profile of the constituent elements of the cluster ions in the thickness direction. In order to make the peak of the hydrogen concentration profile lie in the surface portion of the semiconductor wafer 10 on the epitaxial layer side even after the formation of the epitaxial layer, the acceleration voltage of the cluster ions is set to higher than 0 keV/Cluster and less than 200 keV/Cluster, preferably to 100 keV/Cluster or less, and more preferably to 80 keV/Cluster or less. In addition, for adjusting the acceleration voltage, two methods of (1) electrostatic field acceleration or (2) oscillating field acceleration is commonly used. Examples of the former method include a method in which a plurality of electrodes are arranged at regular intervals, and the same voltage is applied therebetween, thereby forming constant acceleration fields in the direction of the axes. Examples of the latter method include a linear acceleration (linac) method in which ions are transferred in a straight line and accelerated by high-frequency waves.

The dose of the cluster ions can be adjusted by controlling the ion irradiation time. In this embodiment, the dose of hydrogen may be 1×10¹³ atoms/cm² to 1×10¹⁶ atoms/cm², preferably 5×10¹³ atoms/cm² or more. When the hydrogen dose is less than 1×10¹³ atoms/cm², hydrogen would diffusion during the formation of the epitaxial layer, whereas a dose exceeding 1×10¹⁶ atoms/cm² would cause great damage to the surface of the epitaxial layer 20.

Further, when cluster ions including carbon as a constituent element, the dose of carbon is preferably 1×10¹³ atoms/cm² to 1×10¹⁶ atoms/cm², more preferably 5×10¹³ atoms/cm² or more. When the hydrogen dose is less than 1×10¹³ atoms/cm², the gettering capability is not sufficient, whereas a dose exceeding 1×10¹⁶ atoms/cm² would cause great damage to the surface of the epitaxial layer 20.

Note that after the first step and before the second step, it is also preferred to perform recovery heat treatment for recovering crystallinity on the semiconductor wafer 10. Recovery heat treatment here may be performed, for example, by holding the semiconductor wafer 10 in an atmosphere of nitrogen gas, argon gas, or the like at a temperature of 900° C. or more and 1100° C. or less for 10 minutes or longer to 60 minutes or shorter. Alternatively, the recovery heat treatment may be performed using for example a rapid heating/cooling apparatus for rapid thermal annealing (RTA), rapid thermal oxidation (RTO), or the like, separate from the epitaxial apparatus.

The semiconductor wafer 10 can be a silicon wafer as described above.

One embodiment of the method of producing the semiconductor epitaxial wafer 200 has been described, in which the peak of the hydrogen concentration profile detected by SIMS lies in a surface portion of the semiconductor wafer 10 on the side where the epitaxial layer 20 is formed even after the formation of the epitaxial layer 20. However, the disclosed semiconductor epitaxial wafer may naturally be produced by other production methods.

(Method of Producing Solid-State Image Sensing Device)

In a method of producing a solid-state image sensing device according to an embodiment, a solid-state image sensing device can be formed on the epitaxial layer 20 located in the surface portion of the above-described semiconductor epitaxial wafer or on a semiconductor epitaxial wafer produced by the above-described production method, that is, the semiconductor epitaxial wafer 100, 200. In a solid-state image sensing device obtained by this production method, white spot defects can be sufficiently suppressed than conventional.

This disclosure will be described below in more detail using examples. However, this disclosure is not limited to the following examples.

### EXAMPLES

### Examples of Reference Experiments

First, the following experiments were performed to clarify the difference in damage to the surface portion of each silicon wafer between different beam current values of cluster ions.

### Reference Example 1

A p-type silicon wafer (diameter: 300 mm, thickness: 775 μm, dopant: boron, resistivity: 20 Ω·cm) obtained from a CZ single crystal was prepared. Subsequently, a surface of the silicon wafer was irradiated with C₃H₅ cluster ions obtained by making cyclohexane (C₆H₁₂) into cluster ions using a cluster ion generator (CLARIS produced by Nissin Ion Equipment Co., Ltd.) under an irradiation conditions of acceleration voltage: 80 keV/Cluster (acceleration voltage per hydrogen atom: 1.95 keV/atom, acceleration voltage per carbon atom: 23.4 keV/atom, range distance of hydrogen: 40 nm, range distance of carbon: 80 nm), thus fabricating a silicon wafer of Reference Example 1. Note that the dose of the irradiation with cluster ions was 1.6×10¹⁵ atoms/cm² calculated in terms of the number of hydrogen atoms and was 1.0×10¹⁵ atoms/cm² calculated in terms of the number of carbon atoms. The beam current value of the cluster ions was 800 μA.

### Reference Example 2

A silicon wafer of Reference Example 2 was fabricated under the same conditions as Reference Example 1 except that the beam current value of cluster ions was changed to 30 μA.

(Concentration Profile of Silicon Wafer)

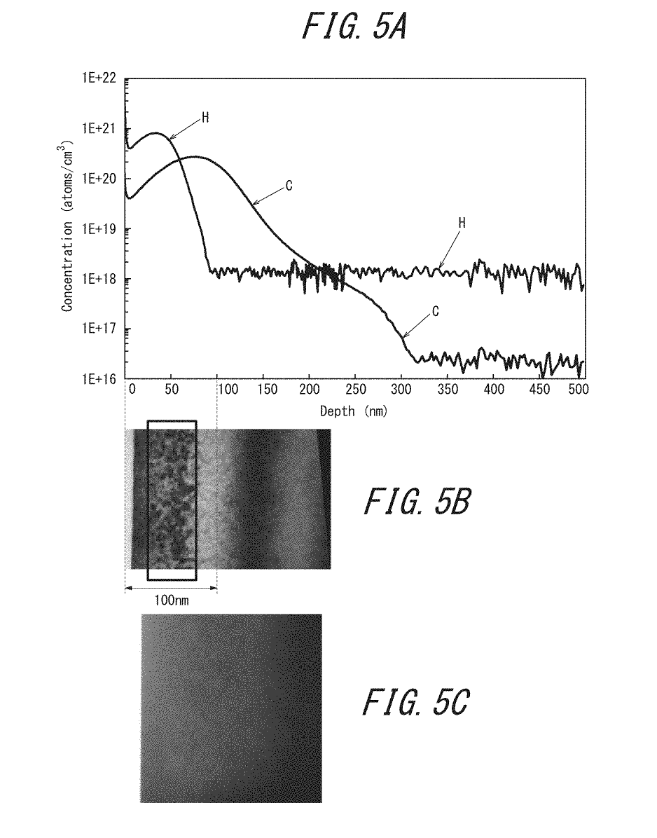

Magnetic sector SIMS measurement was performed on the silicon wafers of Reference Examples 1 and 2 having been irradiated with cluster ions to determine the profiles of the hydrogen concentration and the carbon concentration in the wafer thickness direction. The carbon concentration profile of Reference Example 1 is shown in FIG. 5A as an illustrative example. The same concentration profile as in FIG. 5A was also obtained in Reference Example 2 in which only the beam current value was different. Here, in FIG. 5A, the surface of the silicon wafer on the cluster ion irradiation side corresponds to a depth of 0 on the horizontal axis.

(TEM Cross-Sectional View)

The cross section of the silicon wafer surface portion including the cluster-ion irradiated region of each of the silicon wafers of Reference Examples 1 and 2 was observed using a transmission electron microscope (TEM). The TEM cross-sectional images of the silicon wafers of Reference Examples 1 and 2 are shown in FIGS. 5B and 5C, respectively. The positions where black contrast appears in the area enclosed by the bold rectangle in FIG. 5B are significantly damaged areas.

As shown in FIGS. 5A to 5C, in Reference Example 1 in which the beam current value was 800 μA, significantly damaged areas were formed in the surface portion of the silicon wafer, whereas no significantly damaged areas were formed in Reference Example 2 in which the beam current value was 30 μA. The concentration profiles of hydrogen and carbon in Reference Example 1 and 2 showed similar trends because of the same conditions of the dose; however, whether or not significantly damaged areas were formed in the surface portion of each silicon wafer would be attributed to the difference in the beam current value. Note that FIGS. 5A and 5B indicate that significantly damaged areas were formed in a region between the peak position of the hydrogen concentration and the peak position of the carbon concentration.

### Experimental Examples 1

### Example 1-1

A silicon wafer was irradiated with cluster ions of C₃H₅ under the same conditions as Reference Example 1. Subsequently, the silicon wafer was transferred into a single wafer processing epitaxial growth apparatus (produced by Applied Materials, Inc.) and subjected to hydrogen baking at 1120° C. for 30 s in the apparatus. After that, a silicon epitaxial layer (thickness: 7.8 μm, kind of dopant: boron, resistivity: 10 Ω·cm) was then epitaxially grown on a surface of the silicon wafer by CVD at 1150° C. using hydrogen as a carrier gas and trichlorosilane as a source gas, thereby fabricating an epitaxial silicon wafer of Example 1-1.

### Comparative Example 1-1

An epitaxial wafer of Comparative Example 1-1 was fabricated under the same conditions as Example 1-1 except that the beam current value of cluster ions was changed to 30 μA.

### Conventional Example 1-1

An epitaxial wafer of Conventional Example 1-1 was fabricated under the same conditions as Example 1-1 except that irradiation with cluster ions was not performed.

(Evaluation 1-1: Evaluation of Concentration Profile of Epitaxial Wafer by SIMS)

Magnetic sector SIMS measurement was performed on the silicon wafers of Example 1-1 and Comparative Example 1-1 having been irradiated with cluster ions to determine the profiles of the hydrogen concentration and the carbon concentration in the wafer thickness direction. The concentration profiles of hydrogen and carbon in Example 1-1 is shown in FIG. 6A. Further, the hydrogen concentration profile in Comparative Example 1-1 is shown in FIG. 6B. Here, in each of FIGS. 6A and 6B, the surface of the epitaxial layer corresponds to a depth of 0 on the horizontal axis. Depths up to 7.8 μm correspond to the epitaxial layer, whereas depths equal to 7.8 μm or more correspond to the silicon wafer. When the epitaxial wafers were subjected to SIMS measurement, there would be an inevitable measurement error of approximately ±0.1 μm in the thickness of the epitaxial layer. Accordingly, 7.8 μm in the diagram may not be the exact boundary value between the epitaxial layer and the silicon wafer.

(Evaluation 1-2: Evaluation of TO-Line Intensity by CL Spectroscopy)

Samples processed by beveling the epitaxial wafers of Example 1-1, Comparative Example 1-1, and Conventional Example 1-1 by polishing were subjected to CL spectroscopy from the cross-sectional direction, thereby obtaining the CL spectrum of each epitaxial layer in the thickness (depth) direction. Under a measurement condition of 33 K, irradiation with an electron beam was performed at 20 keV. The measurement results of the CL intensities in the thickness direction in Example 1-1 and Conventional Example 1-1 are shown in FIG. 7. Note that the measurement results of Comparative Example 1-1 were the same as those of Conventional Example 1-1.

As described with reference to FIG. 5A, after cluster ion irradiation, but before the formation of an epitaxial layer, the peak of the hydrogen concentration lied in the surface portion of the silicon wafer irrespective of the beam current value (see Reference Examples 1 and 2 of the reference experiments). Here, the results of Reference Example 1 and Example 1-1, in which the beam current value was 800 μA, show that the peak concentration of hydrogen before the formation of the epitaxial layer was about 7×10²⁰ atoms/cm³, and the peak concentration of hydrogen after the formation of the epitaxial layer decreased to about 2×10¹⁸ atoms/cm³ (FIG. 5A and FIG. 6A). On the other hand, when the beam current value was 30 μA, the peak concentration of hydrogen appeared before the formation of the epitaxial layer; however, the peak of the hydrogen concentration did not appear after the formation of the epitaxial layer (FIG. 6B). When the beam current value was 800 μA, since the surface portion of the silicon wafer was greatly damaged, hydrogen would have remained without being completely diffused by heat treatment for forming the epitaxial layer. This may also be deemed to be a phenomenon in which hydrogen was trapped in the damaged region shown in FIG. 5B.

Further, as shown in FIG. 7, in Example 1-1, the peak of the TO-line intensity lies in a position at a depth of about 7 μm from the epitaxial layer surface. On the other hand, in the epitaxial wafer of Conventional Example 1-1, the TO-line intensity gradually decreases from the boundary of the silicon wafer to the epitaxial layer surface. Note that the value of intensity at the epitaxial layer surface (depth: 0 μm) being a surface is presumed to be affected by the surface level.

### Experimental Examples 2

### Example 2-1

An epitaxial wafer fabricated according to Example 1-1 was subjected to heat treatment at a temperature of 1100° C. for 30 minutes, simulating device fabrication.

### Conventional Example 2-1

As with Example 2-1, an epitaxial wafer fabricated according to Conventional Example 1-1 was subjected to heat treatment at a temperature of 1100° C. for 30 minutes, simulating device fabrication.

(Evaluation 2-1: Evaluation of Concentration Profile of Epitaxial Wafer by SIMS)

As with Evaluation 1-1, Magnetic sector SIMS measurement was performed on the silicon wafer of Example 2-1 having been irradiated with cluster ions to determine the profiles of the hydrogen concentration and the carbon concentration in the wafer thickness direction. The concentration profiles of hydrogen and carbon in Example 2-1 is shown in FIG. 8. Here, as with FIG. 6A, the surface of the epitaxial layer corresponds to a depth of 0 on the horizontal axis.

(Evaluation 2-2: Evaluation of TO-Line Intensity by CL Spectroscopy)

As with Evaluation 1-2, the CL spectra of the epitaxial wafers of Example 2-1 and Conventional Example 2-1 were obtained. The results are shown in FIG. 9.

When comparing FIG. 6A and FIG. 8, the peak concentration of hydrogen in Example 1-1 was about 2×10¹⁸ atoms/cm³, whereas the peak concentration of hydrogen in Example 2-1 decreased to about 3×10¹⁷ atoms/cm³. Further, FIG. 9 shows that in Example 2-1, while the peak of TO-line intensity is kept at a position at a depth of about 7 μm from the epitaxial layer surface (the same position as the peak in FIG. 7), the same level of TO-line intensity as Conventional Example 2-1 was observed in the other areas. Accordingly, an epitaxial wafer satisfying the conditions of this disclosure can be deemed to have an epitaxial layer with higher crystallinity than conventional considering all the factors involved.

The reason for the change in the TO-line intensity is presumed to be that hydrogen passivated point defects included in the epitaxial layer in the epitaxial wafer where hydrogen was observed after the epitaxial growth. On the other hand, since no peak of the hydrogen concentration was observed in Comparative Example 1-1 in which the beam current value was 30 μA, the passivation effect of hydrogen was presumably not obtained in Comparative Example 1-1.

### INDUSTRIAL APPLICABILITY

We can provide a semiconductor epitaxial wafer including an epitaxial layer having higher crystallinity and a method of producing the same. The semiconductor epitaxial wafer provided with such an epitaxial layer can be used to improve the device characteristics of a semiconductor device produced using the wafer.

### REFERENCE SIGNS LIST

10: Semiconductor wafer
10A: Surface of semiconductor wafer
16: Cluster ions
18: Modifying layer
20: Epitaxial layer
100: Semiconductor epitaxial wafer
200: Semiconductor epitaxial wafer

1. A semiconductor epitaxial wafer in which an epitaxial layer is formed on a surface of a semiconductor wafer,
wherein a peak of a hydrogen concentration profile detected by SIMS lies in a surface portion of the semiconductor wafer on a side where the epitaxial layer is formed.

2. The semiconductor epitaxial wafer according to claim 1, wherein the peak of the hydrogen concentration profile lies at a position within a depth range of 150 nm in the thickness direction from the surface of the semiconductor wafer.

3. The semiconductor epitaxial wafer according to claim 1, wherein the peak concentration of the hydrogen concentration profile is 1.0×10¹⁷ atoms/cm³ or more.

4. The semiconductor epitaxial wafer according to claim 1, wherein the semiconductor wafer has a modifying layer containing carbon as a solid solution in the surface portion, and the half width of the peak of a carbon concentration profile of the modifying layer in the direction of the thickness of the semiconductor wafer is 100 nm or less.

5. The semiconductor epitaxial wafer according to claim 4, wherein the peak of the carbon concentration profile lies at a position within a depth range of 150 nm in the thickness direction from the surface of the semiconductor wafer.

6. The semiconductor epitaxial wafer according to claim 1, wherein the semiconductor wafer is a silicon wafer.

7. A method of producing the semiconductor epitaxial wafer according to claim 1, comprising:
a first step of irradiating a surface of a semiconductor wafer with cluster ions including hydrogen as a constituent element; and
a second step of forming an epitaxial layer on the surface of the semiconductor wafer after the first step,
wherein in the first step, a beam current value of the cluster ions is 50 μA or more.

8. The method of producing the semiconductor epitaxial wafer, according to claim 7, wherein in the first step, the beam current value is 5000 μA or less.

9. The method of producing the semiconductor epitaxial wafer, according to claim 7, wherein the cluster ions further include carbon as a constituent element.

10. The method of producing the semiconductor epitaxial wafer, according to claim 7, wherein the semiconductor wafer is a silicon wafer.

11. A method of producing a solid-state image sensing device, wherein a solid-state image sensing device is formed on the epitaxial layer of the epitaxial wafer according to claim 1.

12. A method of producing a solid-state image sensing device, wherein a solid-state image sensing device is formed on the epitaxial layer of the epitaxial wafer according to the epitaxial wafer produced by the production method according to claim 7.
